(19) United States
(12) Patent Application Publication
(10) Pub. No.: US 2007/0241387 A1
(43) Pub. Date: Oct. 18, 2007

(54) Nonvolatile semiconductor memory device

(75) Inventor: Hiroshi Onoda, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 11/727,914

(22) Filed: Mar. 29, 2007

(30) Foreign Application Priority Data
Apr. 13, 2006 (JP) 2006-111012

(51) Int. Cl. H01L 29/76

(52) U.S. Cl. 257/314

(57) ABSTRACT

An SOI substrate is comprised of a support substrate, a buried insulating layer and a semiconductor layer. A 1poly-type memory cell has a pair of source/drain regions, a floating gate electrode layer, and a control gate impurity diffusion region. An isolation insulating layer extends from a surface of the semiconductor layer to reach the buried insulating layer while surrounding the periphery of the control gate impurity diffusion region thereby to separate a region in which the source/drain regions are formed and the control gate impurity diffusion region from each other. Therefore, a nonvolatile semiconductor can be obtained which can prevent a parasitic bipolar operation and is suitable for higher integration.

### BACKGROUND OF THE INVENTION

1. Field of the Invention

The present invention relates to a nonvolatile semiconductor memory device.

2. Description of the Background Art

Applications of nonvolatile semiconductor memory devices are divided into the relatively mass storage application and the small capacity application. The former is the application of data storage for music or images or code storage, with a capacity of a few hundreds of kbits. The latter is the application of (1) storage of address data of LAN (local Area Network) or the like or encryption data for security and (2) trimming of a resistance element, with the capacity of at most a few kbits.

In general, a nonvolatile semiconductor memory device refers to the former, which is technically mainstream. However, the latter application has been present for a long time and has been demanded in particular for Mixed Signal IC (Integrated Circuit).

However, the mass-storage nonvolatile semiconductor memory device, which is technically mainstream, is of a so-called 2poly type in which both of a floating gate and a control gate in a memory cell are generally formed of polysilicon. Therefore, the memory cell is fabricated through complicated processes and therefore is not suitable for the small capacity application.

Therefore, a memory cell for use in the small capacity application is desirably of a so-called 1poly type in which a floating gate is formed of polysilicon and a control gate is formed of an impurity diffusion region.

Such a 1poly-type nonvolatile semiconductor memory device is disclosed, for example, in Japanese Patent Laying-Open Nos. 10-308461, 2001-185632, 2001-229690, and 2001-257324.

However, the conventional 1poly-type nonvolatile semiconductor memory device has the following problems. In order to explain the problems, first, an operation of a flash memory NOR-type cell (2poly type), which is a typical nonvolatile memory, will be described.

In a writing operation, for example, a voltage Vcg applied to a control gate is set to 10V, a voltage Vd applied to a drain is set to 5V, and voltages Vs, Vbg applied to a source and a back gate are set to 0V. Accordingly, electrons are injected to a floating gate by so-called CHE (Channel Hot Electron).

In an erasing operation, for example, voltage Vcg applied to a control gate is set to −20V, voltage Vd applied to a drain is set open, and voltages Vs, Vbg applied to a source and a back gate are set to 0V. Accordingly, a high electric field is applied to a tunnel oxide film under the floating gate so that electrons are removed from the floating gate to a substrate-side positive hole accumulation layer by so-called F-N (Fowler-Nordheim).

In this erasing operation, in a memory cell, a p-well region having n-type source/drain is surrounded with a deep, n-well region to allow a positive potential to be applied to the p-well region (back gate). Accordingly, the voltage applied to the control gate electrode can be divided between the control gate electrode and the p-well region (back gate) so that the voltage applied to the control gate electrode layer can be halved.

In use of such a technique, the application conditions in the erasing operation are: Vcg=−10V, Vd=open, Vs, Vbg=10V.

In a reading operation, for example, voltage Vcg applied to a control gate is set to 5V, voltage Vd applied to a drain is set to 1V, and voltages Vs, Vbg applied to a source and a back gate are set to 0V. Then, using that the threshold voltage of a memory cell varies depending on the electron accumulation state in the floating gate, data in the memory cell is determined depending on the state of the current flowing between source and drain.

Table 1 illustrates applied voltages to each terminal in writing, erasing and reading operations.

TABLE 1
Applied Voltage to Each Terminal in NOR-type Flash Operation

| | | | | back gate |
|---|---|---|---|---|
| | drain | control gate | source | (p-type well) |
| writing | positive | positive | GND | GND |
| operation | voltage | voltage | | |
| | (4 to 7 V) | (9 to 15 V) | | |
| erasing | OPEN | negative | GND | GND |
| operation | | voltage | | |
| | | (−18 to −30 V) | | |
| | OPEN | negative | same | positive |
| | | voltage | potential | voltage |
| | | (−9 to −15 V) | as back gate | (9 to 12 V) |
| reading | positive | positive | GND | GND |
| operation | voltage | voltage | | |
| | (0.6 to 2.5 V) | (4 to 7 V) | | |

A 1poly-type memory cell usually has a control gate formed of an impurity diffusion region formed at a semiconductor substrate. When an n-type impurity diffusion region (for example, n-type well) formed at a surface of a p-type semiconductor substrate is used as such a control gate, a positive voltage can be applied to the n-type impurity diffusion region.

However, when a negative voltage is applied to this n-type impurity diffusion region, the p-type region of the semiconductor substrate and the n-type impurity diffusion region as a control gate are biased in the forward direction so that a large current flows thereby disabling the operation. In a case where a negative voltage is also applied to a control gate, the control gate needs to be formed with a p-type impurity diffusion region and the periphery of the p-type impurity diffusion region needs to be surrounded with an n-type impurity diffusion region (for example, a deep, n-type well), so that the p-type region of the semiconductor substrate and the p-type impurity diffusion region as a control gate are separated from each other by the n-type impurity diffusion region.

In such a configuration, when a negative voltage is applied to a control gate, the negative voltage is applied only to the p-type impurity diffusion region as a control gate. When a positive voltage is applied to a control gate, the positive voltage is applied to both of the p-type impurity diffusion region as a control gate and the n-type impurity diffusion region, which are short-circuited. Accordingly, when a negative voltage is applied to a control gate, the p-type impurity diffusion region as a control gate and the n-type impurity diffusion region are biased in the reverse direction. When a positive voltage is applied to a control gate, the n-type impurity diffusion region and the p-type region of the semiconductor substrate are biased in the reverse direction. Thus, in either case, a large current flow can be prevented.

Therefore, in a case of a p-type semiconductor substrate for use in a normal CMOS (Complementary Metal Oxide Semiconductor) transistor, when a 1poly-type memory cell is operated in such a manner that positive and negative different voltages are applied to an impurity diffusion region corresponding to a control gate, a double diffusion layer is required in which a p-type impurity diffusion layer is surrounded with an n-type impurity diffusion region. Accordingly, the p-type impurity diffusion region as a control gate, the n-type impurity diffusion region and the p-type region of the semiconductor substrate operate as parasitic bipolar, causing an operating error.

Moreover, when a double diffusion layer is provided, the two-dimensional occupation area of a memory cell is relatively large, in consideration of the diffusion length of an n-type impurity in the n-type impurity diffusion region. Therefore, this memory cell is not suitable for higher integration.

### SUMMARY OF THE INVENTION

The present invention is made to solve the aforementioned problems. An object of the present invention is to provide a nonvolatile semiconductor memory device which can prevent a parasitic bipolar operation and is suitable for higher integration.

A nonvolatile semiconductor memory device in accordance with the present invention includes a support substrate, a buried insulating layer, a pair of impurity diffusion regions, a floating gate electrode layer, a control gate impurity diffusion region, and a first isolation insulating layer. The buried insulating layer is formed on the support substrate. The semiconductor layer is formed on the buried insulating layer. A pair of impurity diffusion regions is formed at a surface of the semiconductor layer and serves as source/drain. The floating gate electrode layer is formed on the semiconductor layer sandwiched between the pair of impurity diffusion regions with a gate insulating layer interposed. The control gate impurity diffusion region is formed at a surface of the semiconductor layer to oppose the floating gate electrode layer with an inter-gate insulating layer interposed. The first isolation insulating layer extends from a surface of the semiconductor layer to reach the buried insulating layer while surrounding a periphery of the control gate impurity diffusion region thereby to separate a region in which the pair of impurity diffusion regions is formed and the control gate impurity diffusion region from each other.

According to the nonvolatile semiconductor memory device in the present invention, the first isolation insulating layer extends from a surface of the semiconductor layer to reach the buried insulating layer while surrounding the periphery of the control gate impurity diffusion region. Therefore, the control gate impurity diffusion region has the side portion surrounded with the first isolation insulating layer and the bottom portion covered with the buried insulating layer. In this manner, the periphery of the control gate impurity diffusion region is surrounded with the first isolation insulating layer and the buried insulating layer and is isolated and insulated from other element formation regions, so that either a positive voltage or a negative voltage can be applied to the control gate impurity diffusion region.

In addition, since the control gate impurity diffusion region is isolated and insulated from other element formation regions, the parasitic bipolar operation does not occur even when voltage is applied to the control gate impurity diffusion region.

Moreover, since the control gate impurity diffusion region is isolated and insulated from other element formation regions by the isolation insulating layer, unlike the conventional example, the diffusion length of an impurity does not have to be considered in isolating elements from each other. Therefore, the two-dimensional occupation area of a memory cell can be reduced compared with the conventional example, so that a memory cell suitable for higher integration can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view schematically showing a configuration of a nonvolatile semiconductor memory device in a first embodiment of the present invention.

FIG. 2 is a cross sectional view showing a state in an erasing operation in the nonvolatile semiconductor memory device in the first embodiment of the present invention.

FIG. 3-FIG. 13 are schematic cross sectional views showing the steps of a method of manufacturing the nonvolatile semiconductor memory device in the first embodiment of the present invention, in order.

FIG. 14A and FIG. 14B show two-dimensional layouts where a formation region of a source/drain region 11 and a formation region of a control gate impurity diffusion region 14 are separated by an n-type well 105 and by an isolation insulating layer 6, respectively, in a memory cell.

FIG. 15 is a cross sectional view schematically showing a configuration of a nonvolatile semiconductor memory device in a second embodiment of the present invention.

FIG. 16 is a cross sectional view schematically showing a configuration of a nonvolatile semiconductor memory device in the second embodiment of the present invention.

FIG. 17 is a cross sectional view schematically showing a configuration of a nonvolatile semiconductor memory device in a third embodiment of the present invention.

FIG. 18 is a cross sectional view schematically showing a configuration of a nonvolatile semiconductor memory device in a fourth embodiment of the present invention.

FIG. 19 is a two-dimensional layout view schematically showing a part of a memory cell array as a configuration of a nonvolatile semiconductor memory device in a fifth embodiment of the present invention.

FIG. 20 is a schematic cross sectional view along line XX-XX in FIG. 19.

FIG. 21 is a two-dimensional layout view schematically showing a part of a memory cell array as a configuration of a nonvolatile semiconductor memory device in a sixth embodiment of the present invention.

FIG. 22 is a schematic cross sectional view along line XXII-XXII in FIG. 21.

FIG. 23 is a cross sectional view schematically showing a configuration of a nonvolatile semiconductor memory device in a seventh embodiment of the present invention.

FIG. 24 is a diagram showing a state of a changed capacity value when a control gate voltage Vcg is changed in the configuration shown in FIG. 23.

FIG. 25 is a cross sectional view of a first example showing a configuration in which an isolation insulating layer covers a sidewall of a groove and another filling layer is buried in the groove.

FIG. 26 is a cross sectional view of a second example showing a configuration in which an isolation insulating layer covers a sidewall of a groove and another filling layer is buried in the groove.

FIG. 27 is a cross sectional view of a third example showing a configuration in which an isolation insulating layer covers a sidewall of a groove and another filling layer is buried in the groove.

FIG. 28-FIG. 32 are schematic cross sectional views showing the steps of a method of manufacturing a nonvolatile semiconductor memory device in an eighth embodiment of the present invention, in order.

### DESCRIPTION OF THE PREFERRED EMBODIMENTS

In the following, embodiments of the present invention will be described based on the figures.

It is noted that in the following description of the embodiments, the operation of NOR-type flash memory as described above will be described by way of example. However, the present invention is not limited to the operation as described below and is applicable to any other nonvolatile semiconductor memory device.

### First Embodiment

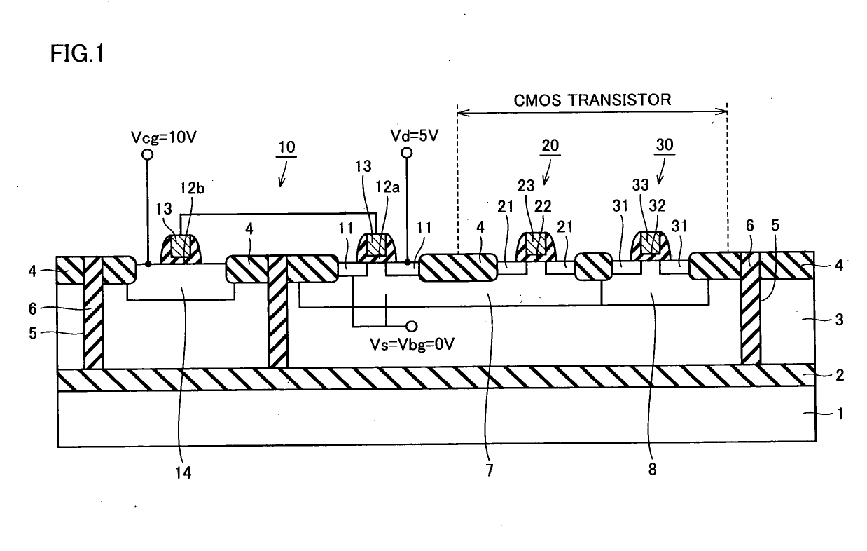

Referring to FIG. 1, in the present embodiment, a 1poly-type memory cell 10 is formed at SOI (Silicon on Insulator) substrate 1, 2, 3.

The SOI substrate has a support substrate 1, a buried insulating layer 2 formed, for example, of a silicon oxide film on support substrate 1, and an n⁻ or p⁻ semiconductor layer 3 formed, for example, of silicon on buried insulating layer 2. A field insulating layer 4 formed, for example, of a silicon oxide film is formed at a part of the surface of semiconductor layer 3. Here, buried insulating layer 2 is for example a BOX (Buried Oxide) layer.

The 1poly-type memory cell 10 mainly has a pair of n-type source/drain regions 11, 11, a floating gate electrode layer 13, and a control gate impurity diffusion region 14. A pair of source/drain regions 11, 11 is formed at a surface of a p-type well 7 formed at the surface of semiconductor layer 3. Floating gate electrode layer 13 is formed, for example, of polysilicon doped with an impurity and is positioned on a region sandwiched between a pair of source/drain regions 11, 11 with a gate insulating layer 12a interposed on semiconductor layer 3. Control gate impurity diffusion region 14 is an n⁺ region or a p⁺ region formed at that surface of semiconductor layer 3 which is separated from p-type well 7 by field insulating layer 4. Control gate impurity diffusion region 14 preferably has an impurity concentration of 1×10¹⁸/cm³ or more to prevent depletion at the time of voltage application. Floating gate electrode layer 13 extends onto control gate impurity diffusion region 14 and is electrically insulated from control gate impurity diffusion region 14 by an inter-gate insulating layer 12b. Here, a sidewall of floating gate electrode layer 13 is covered with a sidewall insulating layer.

A groove 5 is formed in semiconductor layer 3 to surround the periphery of control gate impurity diffusion region 14. Groove 5 extends from the upper surface of field insulating layer 4, passes through field insulating layer 4 to the surface of semiconductor layer 3, and then reaches the buried insulating layer 2. An isolation insulating layer 6 formed, for example, of a silicon oxide film is filled in groove 5. Accordingly, isolation insulating layer 6 extends from the surface of semiconductor layer 3 to buried insulating layer 2 while surrounding the periphery of control gate impurity diffusion region 14 and separates control gate impurity diffusion region 14 from a region in which a pair of source/drain regions 11 is formed.

In this embodiment, CMOS transistors 20, 30 are formed together with 1poly-type memory cell 10. CMOS transistors 20, 30 are formed of an n-channel MOS (referred to as nMOS hereinafter) transistor 20 and a p-channel MOS (referred to as pMOS hereinafter) transistor 30.

The nMOS transistor 20 mainly has a pair of n-type source/drain regions 21, 21 and a gate electrode layer 23. A pair of n-type source/drain regions 21, 21 are formed at a surface of p-type well 7. Gate electrode layer 23 is positioned on a region sandwiched between a pair of n-type source/drain regions 21, 21 with a gate insulating layer 22 interposed on semiconductor layer 3. Gate electrode layer 23 is formed, for example, of polysilicon doped with an impurity, and gate insulating layer 22 is formed, for example, of a silicon oxide film.

The pMOS transistor 30 mainly has a pair of p-type source/drain regions 31, 31 and a gate electrode layer 33. A pair of p-type source/drain regions 31, 31 are formed on a surface of an n-type well 8 formed at a surface of semiconductor layer 3. Gate electrode layer 33 is positioned on a region sandwiched between a pair of p-type source/drain regions 31, 31 with a gate insulating layer 32 interposed on semiconductor layer 3. Gate electrode layer 33 is formed, for example, of polysilicon doped with an impurity, and gate insulating layer 32 is formed, for example, of a silicon oxide film.

Source/drain region 11 of 1poly-type memory cell 10 and CMOS transistors 20, 30 are not isolated from each other by isolation insulating layer 6 and are each formed in a region surrounded with isolation insulating layer 6. The sidewalls of gate electrode layers 23, 33 are also covered with sidewall insulating layers.

Now, the writing, erasing and reading operations of the 1poly-type memory cell 10 in the present embodiment will be described.

Referring to FIG. 1, in writing data, voltage Vcg of about 10V is applied to control gate impurity diffusion region 14, voltage Vd of about 5V is applied to drain region 11, and voltages Vs, Vbg of 0V are applied to source region 11 and p-type well 7 as a back gate. Accordingly, a number of high energy electrons are produced in the vicinity of drain region 11 and gate insulating layer 12a. A part of the electrons are injected into floating gate electrode layer 13. In this manner, electrons are accumulated in floating gate electrode layer 13 thereby increasing threshold voltage Vth of the memory transistor. This state in which the threshold voltage is increased is a written state.

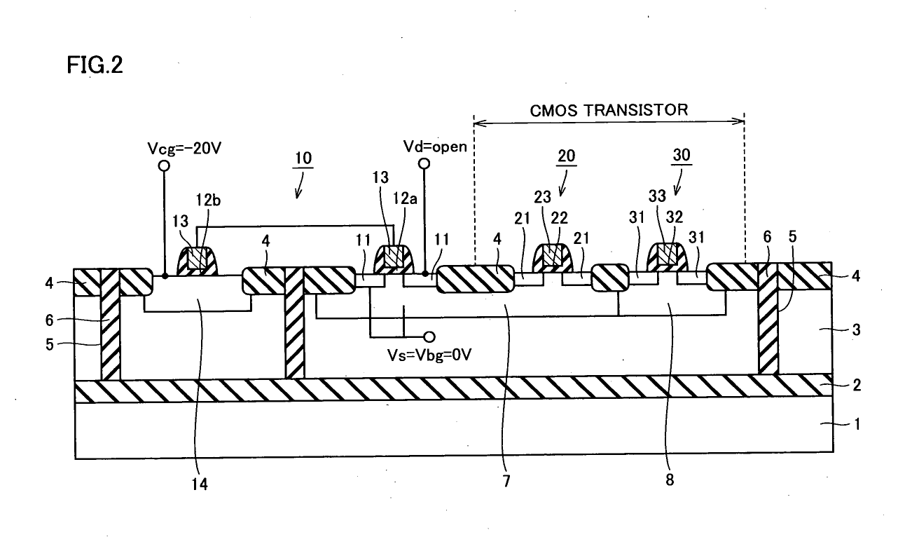

Referring to FIG. 2, in erasing data, voltage Vcg of about −20V is applied to control gate impurity diffusion region 14, voltage Vd of drain region 11 is set to an open state, and voltages Vs, Vbg of 0V are applied to source region 11 and p-type well 7 as a back gate. Accordingly, a high electric field is applied to gate insulating layer (tunnel insulating film) 12a under floating gate electrode layer 13 so that electrons are removed from floating gate electrode layer 13 to a substrate-side positive hole accumulation layer by so-called F-N. In this manner, electrons in floating gate electrode layer 13 are removed thereby decreasing threshold voltage Vth of the memory transistor. This state in which the threshold voltage is decreased is an erased state.

Furthermore, in reading data, voltage Vcg of about 5V is applied to control gate impurity diffusion region 14, and voltage Vd of about 1-2V is applied to drain region 11. Here, data determination is made depending on whether current flows in the channel region of the memory transistor, or whether the memory transistor is in on-state or off-state.

Table 2 illustrates applied voltages to each terminal in the aforementioned writing, erasing and reading operations.

TABLE 2

| | | control gate | | back gate |
|---|---|---|---|---|
| | drain | layer | source | (p-type well) |
| writing | positive | positive | GND | GND |
| operation | voltage | voltage | | |
| | (4 to 7 V) | (9 to 15 V) | | |
| erasing | OPEN | negative | GND | GND |
| operation | | voltage | | |
| | | (−18 to −30 V) | | |
| reading | positive | positive | GND | GND |
| operation | voltage | voltage | | |
| | (0.6 to 2.5 V) | (4 to 7 V) | | |

Now, a method of manufacturing the nonvolatile semiconductor memory device in this embodiment will be described, with attention, in particular, to formation of a groove in a semiconductor layer and filling the groove with an isolation insulating layer.

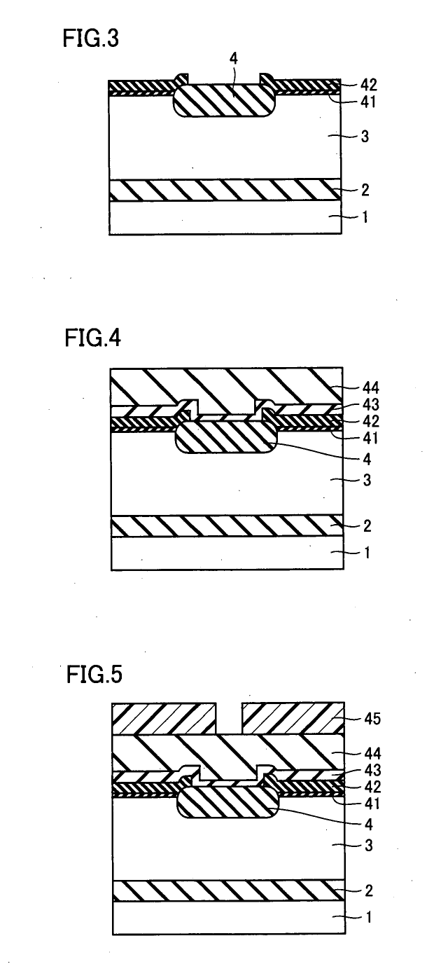

First, referring to FIG. 3, buried insulating layer 2 and semiconductor layer 3 are formed on support substrate 1 in a stacked manner. A well region and the like are formed in semiconductor layer 3. A silicon oxide film 41 and a silicon nitride film 42 are stacked in order on the surface of semiconductor layer 3. Thereafter, silicon nitride film 42 is patterned by a photolithography technique and an etching technique. A portion exposed from the patterned silicon nitride film 42 is oxidized by thermal oxidation, resulting in field insulating layer 4 formed of a silicon oxide film.

Referring to FIG. 4, a silicon nitride film 43 and a TEOS (Tetra Ethyl Ortho Silicate) oxide film 44 are formed on the entire surface. Thereafter, nitrogen annealing is performed.

Referring to FIG. 5, a photoresist 45 is applied on TEOS oxide film 44 and patterned by a photolithography technique. Using the patterned photoresist 45 as a mask, anisotropic etching is performed. After this etching, photoresist 45 is removed, for example, by ashing or the like.

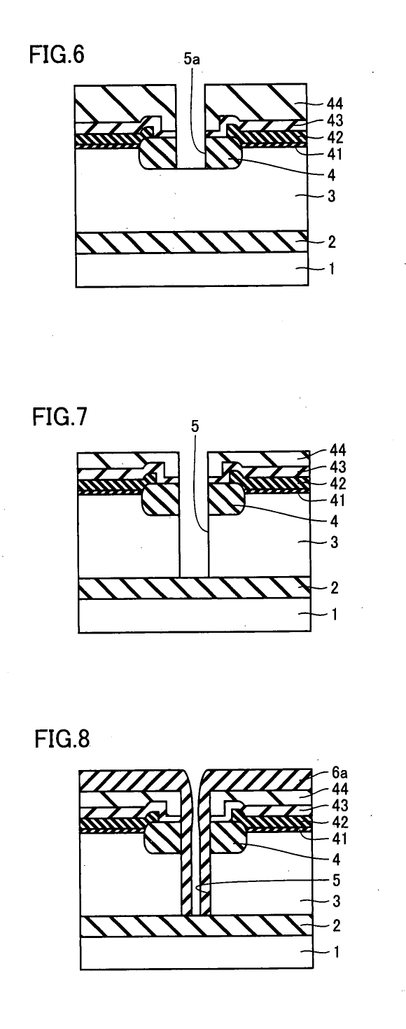

Referring to FIG. 6, TEOS oxide film 44, silicon nitride films 43, 42 and field insulating layer 4 are successively etched by the aforementioned etching, resulting in a groove 5a. Thereafter, etching for forming a trench is performed on semiconductor layer 3 exposed from groove 5a.

Referring to FIG. 7, the aforementioned etching reduces the film thickness of TEOS oxide film 44 and, in addition, forms groove 5 in semiconductor layer 3.

Referring to FIG. 8, a TEOS oxide film 6a is formed to overlie TEOS oxide film 44 and cover at least the sidewall of groove 5a. Thereafter, annealing is performed.

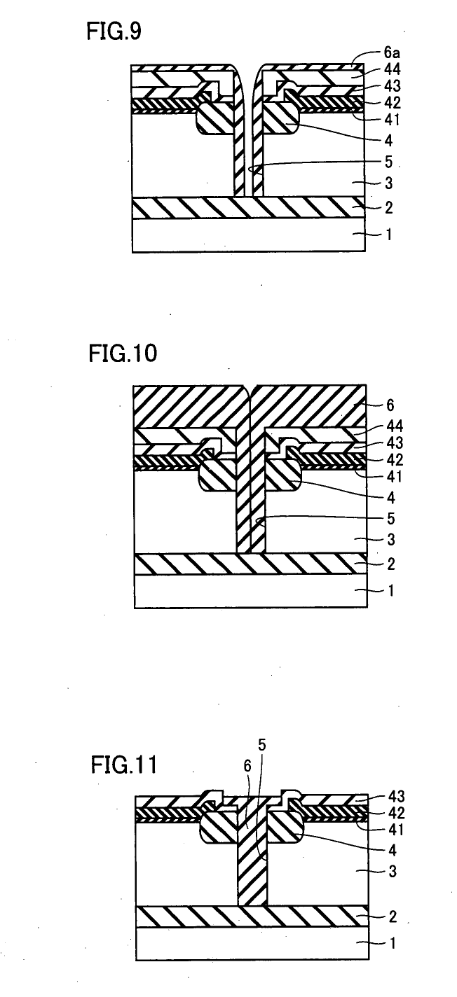

Referring to FIG. 9, TEOS oxide film 44 is etched back so that the film thickness is reduced.

Referring to FIG. 10, a TEOS oxide film is deposited again to form TEOS oxide film 6 which fills in groove 5. TEOS oxide film 6a and the subsequently deposited TEOS oxide film are collectively shown as TEOS oxide film 6. Thereafter, TEOS oxide films 6 and 44 are etched away until the surface of silicon nitride film 43 is exposed.

Referring to FIG. 11, the aforementioned etching is further continued until the surface of silicon nitride film 43 is completely exposed.

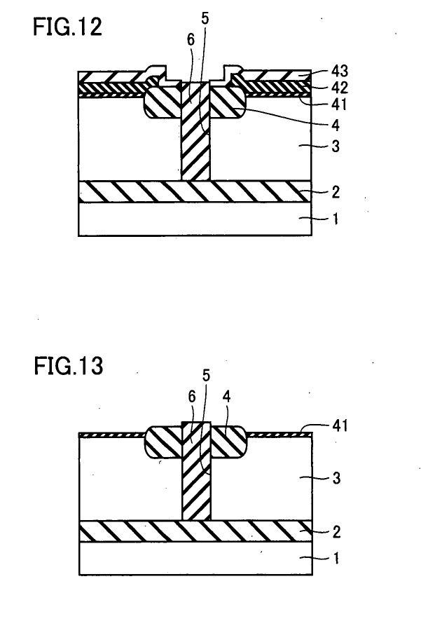

Referring to FIG. 12, the surface of silicon nitride film 43 is completely exposed by the aforementioned etching. The exposed silicon nitride film 43 and the underlying silicon nitride film 42 are successively removed by etching.

Referring to FIG. 13, the surface of silicon oxide film 41 is exposed by etching the silicon nitride films as described above. Through the aforementioned steps, groove 5 is formed in semiconductor layer 3 and isolation insulating layer 6 is formed to fill in groove 5.

Thereafter, floating gate electrode layer 13, gate electrode layers 23, 33, source/drain regions 11, 21, 31, and the like are formed, thereby completing the nonvolatile semiconductor memory device shown in FIG. 1.

According to the present embodiment, isolation insulating layer 6 extends from the surface of semiconductor layer 3 to reach buried insulating layer 2 while surrounding the periphery of control gate impurity diffusion region 14. Therefore, control gate impurity diffusion region 14 has the side portion surrounded with isolation insulating layer 6 and has the bottom portion covered with buried insulating layer 2. In this manner, the periphery of control gate impurity diffusion region 14 is surrounded with isolation insulating layer 6 and buried insulating layer 2 and is isolated and insulated from other element formation regions (for example, source/drain region 11 of memory cell 10, CMOS transistors 20, 30 and the like), so that either a positive voltage or a negative voltage can be applied to control gate impurity diffusion region 14.

In addition, since control gate impurity diffusion region 14 is isolated and insulated from other element formation regions, the parasitic bipolar operation does not occur even when voltage is applied to control gate impurity diffusion region 14.

Moreover, since control gate impurity diffusion region 14 is isolated and insulated from other element formation regions by isolation insulating layer 6, unlike the conventional example, the diffusion length of an impurity does not have to be considered in isolating elements from each other. Therefore, the two-dimensional occupation area of a memory cell can be reduced compared with the conventional example, so that a memory cell suitable for higher integration can be obtained. This will be described below with reference to the figures.

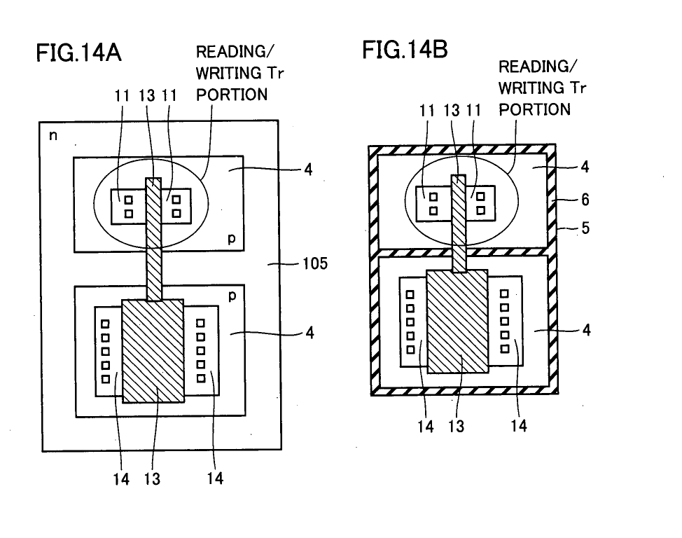

In the case of isolation with an n-type well 105, as shown in FIG. 14A, the diffusion length of an n-type impurity in n-type well 105 needs to be considered. The two-dimensional size of n-type well 105 has to be at least a few μm. On the other hand, in the case of isolation with isolation insulating layer 6, as shown in FIG. 14B, groove 5 filled with isolation insulating layer 6 is fabricated by a photolithography step and has a two-dimensional width set at 0.8 μm or less. In this way, isolation insulating layer 6 which fills in groove 5 is used in place of n-type well 105, so that the two-dimensional occupation area of a memory cell in the present embodiment can be reduced.

### Second Embodiment

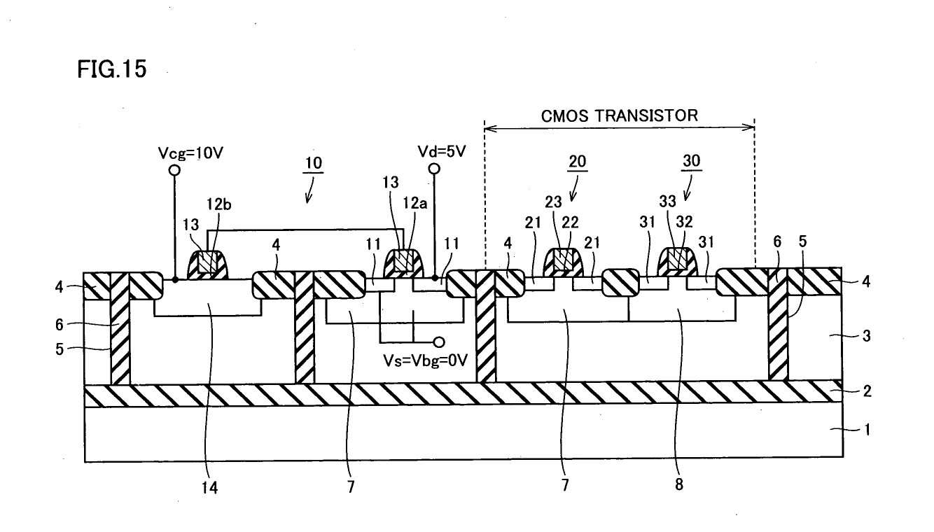

Referring to FIG. 15, in this embodiment, groove 5 is formed in semiconductor layer 3 to surround the periphery of source/drain region 11 and back gate layer (p-type well) 7 of the 1poly-type memory cell 10. Isolation insulating layer 6, for example, formed of a silicon oxide film is filled in this groove 5. Accordingly, isolation insulating layer 6 extends from the surface of semiconductor layer 3 to reach buried insulating layer 2 while surrounding the periphery of source/drain region 11 and back gate (p-type well) 7 and separates source/drain region 11 and back gate (p-type well) 7 from other element formation regions (for example, the formation region of CMOS transistors 20, 30).

Isolation insulating layer 6 surrounding the periphery of source/drain region 11 and back gate (p-type well) 7 and isolation insulating layer 6 surrounding the periphery of control gate impurity diffusion region 14 partially share an insulating layer portion.

The formation region of CMOS transistors 20, 30 also has its periphery surrounded with isolation insulating layer 6 which fills in groove 5.

It is noted that the other configuration is almost the same as the configuration of the first embodiment. Therefore the same elements will be denoted with the same reference characters and a description thereof will not be repeated.

Now, the writing, erasing and reading operations of the 1poly-type memory cell 10 in the present embodiment will be described.

Referring to FIG. 15, in writing data, voltage Vcg of about 10V is applied to control gate impurity diffusion region 14, voltage Vd of about 5V is applied to drain region 11, and voltages Vs, Vbg of 0V are applied to source region 11 and p-type well 7 as a back gate. Accordingly, similarly to the first embodiment, electrons are injected into floating gate electrode layer 13 thereby increasing threshold voltage Vth of the memory transistor. Thus, memory cell 10 is brought into a written state.

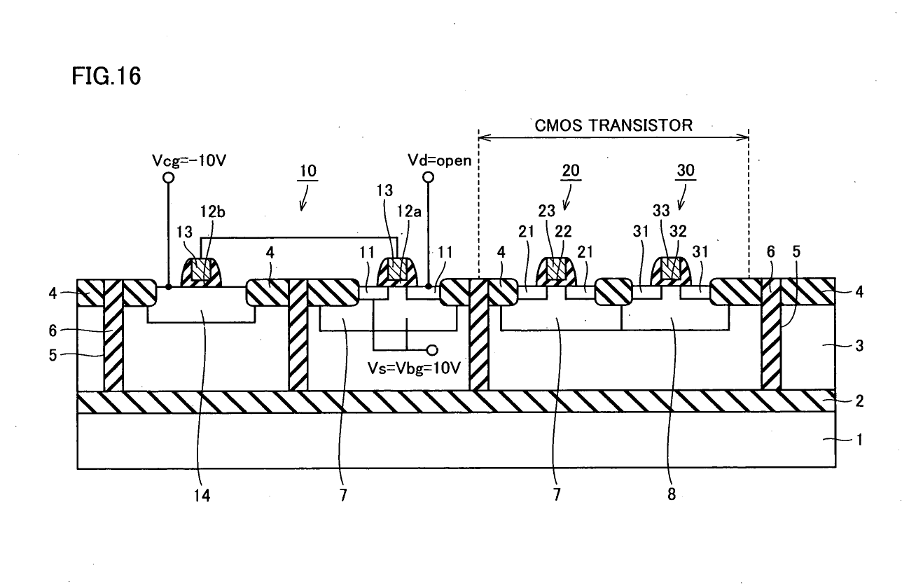

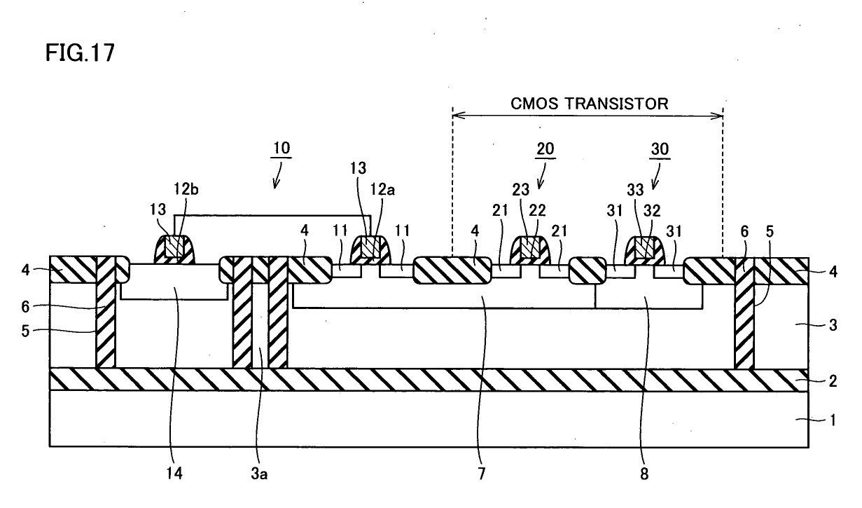

Referring to FIG. 16, in erasing data, voltage Vcg of about −10V is applied to control gate impurity diffusion region 14, voltage Vd of drain region 11 is set to an open state, and voltages Vs, Vbg of 10V are applied to source region 11 and p-type well 7 as a back gate. Here, back gate layer (p-type well) 7 on the nMOS transistor 20 side of the normal CMOS transistors 20, 30 remains at the GND potential. Accordingly, a high electric field is applied to gate insulating layer (tunnel insulating film) 12a under floating gate electrode layer 13 so that electrons are removed from floating gate electrode layer 13 to a substrate-side positive hole accumulation layer by so-called F-N. In this manner, electrons in floating gate electrode layer 13 are removed thereby decreasing threshold voltage Vth of the memory transistor. This state in which the threshold voltage is decreased is an erased state.

Furthermore, in reading data, voltage Vcg of about 5V is applied to control gate impurity diffusion region 14, and voltage Vd of about 1-2V is applied to drain region 11. Here, data determination is made depending on whether current flows in the channel region of the memory transistor, or whether the memory transistor is in on-state or off-state.

Table 3 illustrates applied voltages to each terminal in the aforementioned writing, erasing and reading operations.

TABLE 3

| | | control gate | | back gate |
|---|---|---|---|---|
| | drain | layer | source | (p-type well) |
| writing | positive | positive | GND | GND |
| operation | voltage | voltage | | |
| | (4 to 7 V) | (9 to 15 V) | | |
| erasing | OPEN | negative | same | positive |
| operation | | voltage | potential | voltage |
| | | (−9 to −15 V) | as back gate | (9~12 V) |
| reading | positive | positive | GND | GND |
| operation | voltage | voltage | | |
| | (0.6 to 2.5 V) | (4 to 7 V) | | |

In the present embodiment, isolation insulating layer 6 extends from the surface of semiconductor layer 3 to reach buried insulating layer 2 while surrounding the periphery of control gate impurity diffusion region 14, thereby achieving a similar effect as the first embodiment.

In addition, since isolation insulating layer 6 surrounds the periphery of source/drain region 11 and back gate layer (p-type well) 7, either a positive voltage or a negative voltage can be applied to back gate layer (p-type well) 7. Accordingly, as shown in FIG. 16, voltage required for erasure can be halved between control gate impurity diffusion region 14 and back gate layer (p-type well) 7, thereby reducing the absolute value of the required maximum voltage by half. Thus, size reduction and higher performance of a driving circuit can be achieved.

### Third Embodiment

Referring to FIG. 17, the configuration of the present embodiment differs from the configuration of the first embodiment in that an isolation region 3a formed of a semiconductor layer is provided between isolation insulating layer 6 surrounding the periphery of control gate impurity diffusion region 14 and isolation insulating layer 6 surrounding the periphery of source/drain region 11 and CMOS transistors 20, 30.

It is noted that the other configuration is almost the same as the configuration of the first embodiment. Therefore the same elements will be denoted with the same reference characters and a description thereof will not be repeated.

### Fourth Embodiment

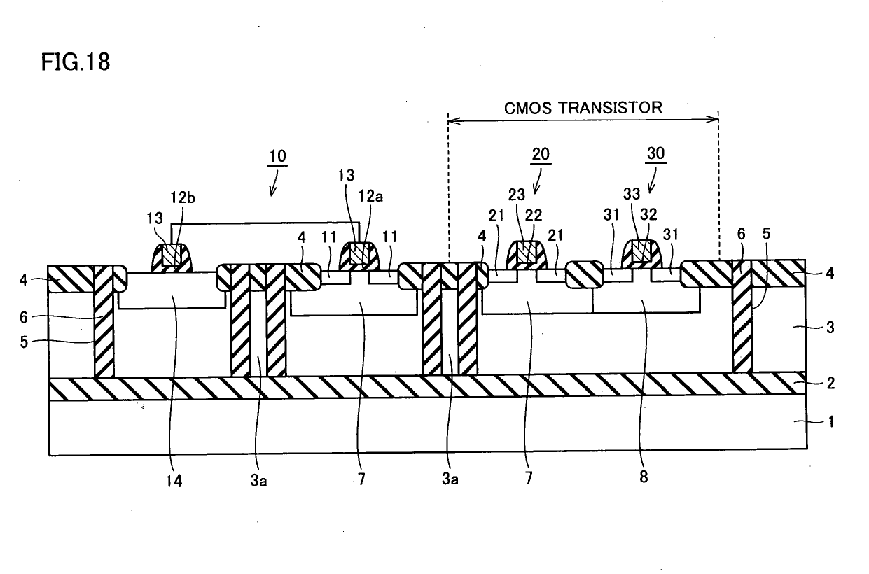

Referring to FIG. 18, the configuration of the present embodiment differs from the configuration of the second embodiment in that (1) isolation region 3a formed of a semiconductor layer is provided between isolation insulating layer 6 surrounding the periphery of control gate impurity diffusion region 14 and isolation insulating layer 6 surrounding the periphery of source/drain region 11 and CMOS transistors 20, 30, and (2) isolation region 3 a formed of a semiconductor layer is provided between isolation insulating layer 6 surrounding the periphery of source/drain region 11 and CMOS transistors 20, 30 and isolation insulating layer 6 surrounding the periphery of CMOS transistors 20, 30.

It is noted that the other configuration is almost the same as the configuration of the second embodiment. Therefore the same elements will be denoted with the same reference characters and a description thereof will not be repeated.

### Fifth Embodiment

In the present embodiment, a specific arrangement configuration of a memory cell in a memory cell array will be described.

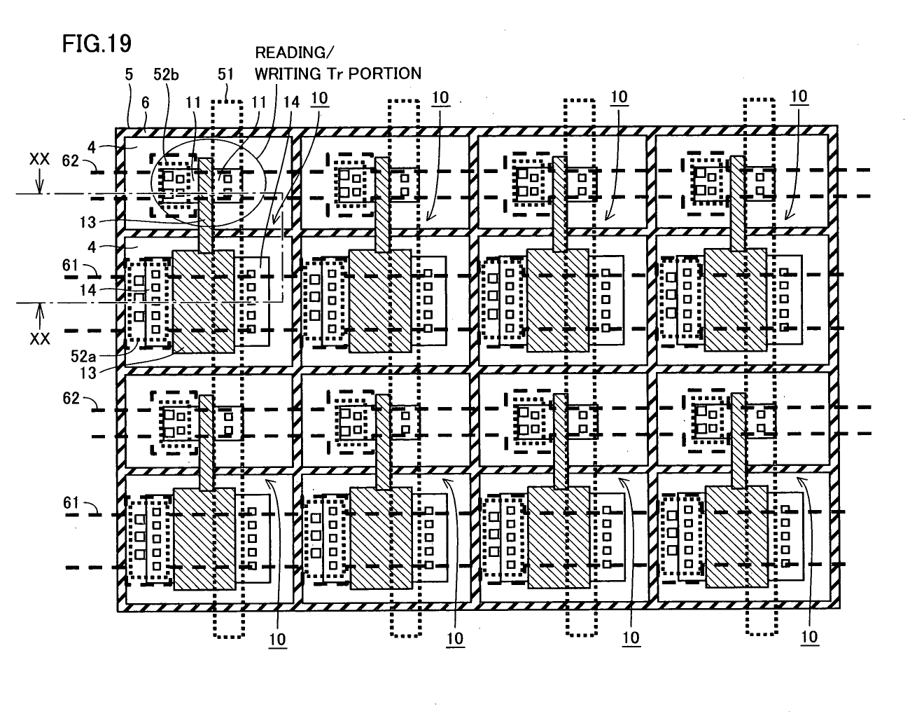

Referring to FIG. 19, a plurality of 1poly-type memory cells 10 are arranged in matrix in a memory cell array. The periphery of each of a plurality of memory cells 10 is surrounded with isolation insulating layer 6. Accordingly, memory cells 10 are isolated and insulated from each other by isolation insulating layer 6.

Furthermore, the periphery of control gate impurity diffusion region 14 in each memory cell 10 is also surrounded with isolation insulating layer 6, and the periphery of source/drain region 11 and back gate layer (p-type well) 7 is also surrounded with isolation insulating layer 6. Accordingly, in each memory cell 10, control gate impurity diffusion region 14 is isolated and insulated from source/drain region 11 and back gate layer (p-type well) 7.

Isolation insulating layer 6 surrounding the periphery of memory cell 10 shares an insulating layer portion between the adjacent memory cells 10. Isolation insulating layer 6 surrounding the periphery of control gate impurity diffusion region 14 and isolation insulating layer 6 surrounding the periphery of source/drain region 11 and back gate layer (p-type well) 7 also share an insulating layer portion at the boundary of each formation region.

A bit line (drain line) 51 is formed on memory cell 10, which is electrically connected to drain region 11 and extends in a column direction (the vertical direction in the figure). A pad layer 52a electrically connected to control gate impurity diffusion region 14 and a pad layer 52b electrically connected to source region 11 are also formed on memory cell 10. These bit line 51 and pad layers 52a, 52b are formed of aluminum of a first layer (lower layer).

In addition, a control gate line 61 is formed on memory cell 10, which is electrically connected to pad layer 52a and extends in the row direction (the horizontal direction in the figure). A source line 62 is also formed on memory cell 10, which is electrically connected to pad layer 52b and extends in the column direction. Control gate line 61 and source line 62 are formed of aluminum of a second layer (upper layer).

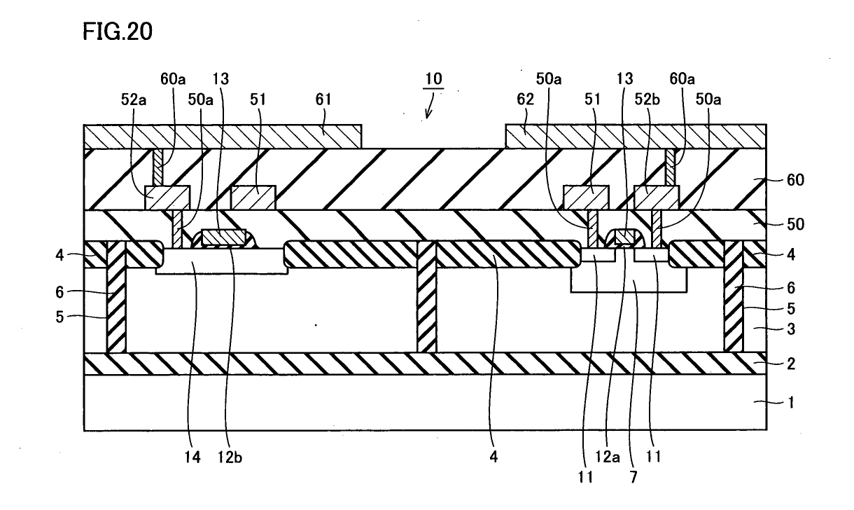

Referring to FIG. 20, the 1poly-type memory cell 10 is formed in SOI substrate 1, 2, 3. The cross sectional structure of SOI substrate 1, 2, 3 and memory cell 10 is substantially identical to the cross sectional structure of the second embodiment shown in FIG. 15. Therefore the same elements will be denoted with the same reference characters and a description thereof will not be repeated.

An interlayer insulating layer 50 is formed to overlie memory cell 10. Bit line 51 and pad layers 52a, 52b are formed on interlayer insulating layer 50. Bit line 51 is electrically connected to drain region 11 through a plug layer 50a. Pad layer 52a is electrically connected to control gate impurity diffusion region 14 through plug layer 50a. Pad layer 52b is electrically connected to source region 11 through plug layer 50a.

Interlayer insulating layer 60 is formed to overlie bit line 51 and pad layers 52a, 52b. Control gate line 61 and source line 62 are formed on interlayer insulating layer 60. Control gate line 61 is electrically connected to pad layer 52a through a plug layer 60a. Source line 62 is electrically connected to pad layer 52b through plug layer 60a.

### Sixth Embodiment

In the fifth embodiment, the configuration including memory cells 10 isolated and insulated from each other by isolation insulating layer 6 has been described. However, memory cells 10 may not be isolated and insulated from each other by isolation insulating layer 6 as long as the formation region of control gate impurity diffusion region 14 and the formation region of source/drain region 11 and back gate layer 7 of each memory cell 10 are isolated and insulated from each other by an isolation insulating layer. Such a configuration will be described below as a configuration of a sixth embodiment.

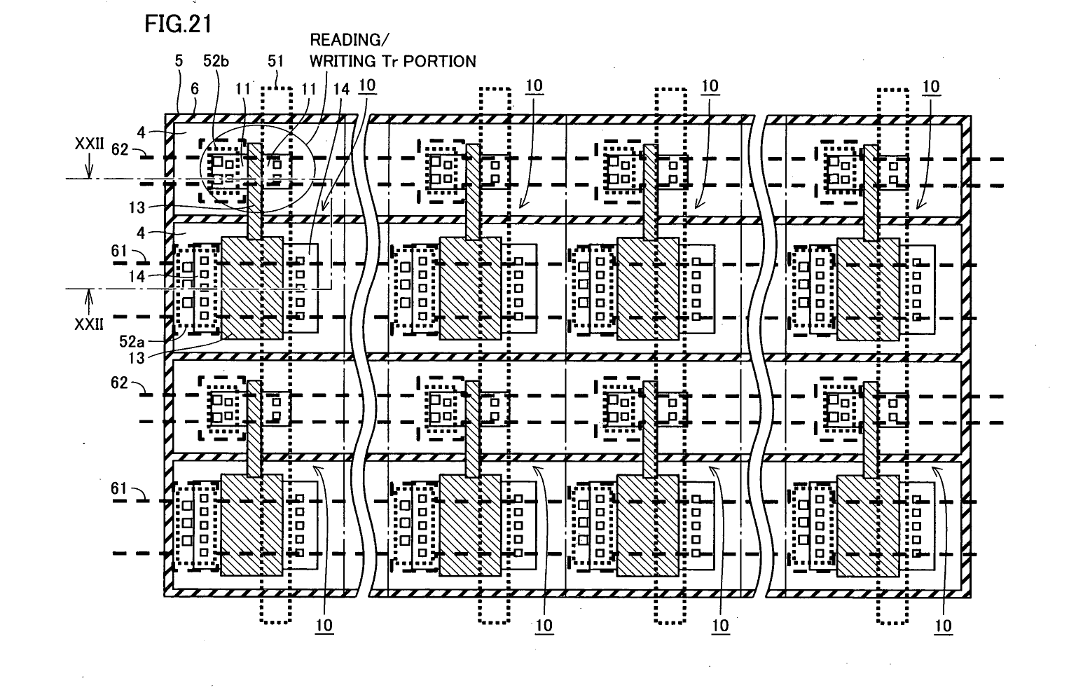

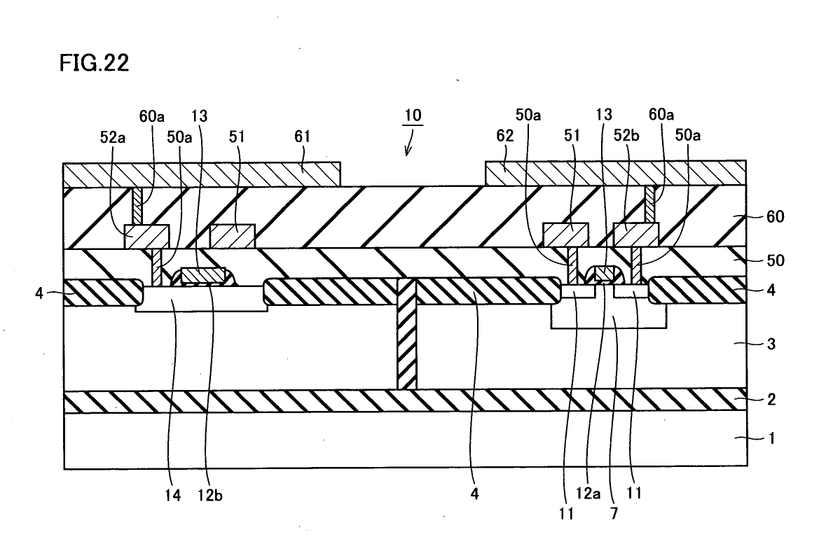

Referring to FIG. 21 and FIG. 22, the configuration of the present embodiment differs from the fifth embodiment in that memory cells 10 are not isolated and insulated from each other by isolation insulating layer 6. It is noted that the formation region of control gate impurity diffusion region 14 and the formation region of source/drain region 11 and back gate layer 7 of each memory cell 10 are isolated and insulated from each other by an isolation insulating layer.

Therefore, in the present embodiment, between adjacent memory cells 10, the formation regions of control gate impurity diffusion region 14 are not isolated from each other by isolation insulating layer 6. Furthermore, between adjacent memory cells 10, the formation regions of source/drain region 11 and back gate layer 7 are not isolated from each other by isolation insulating layer 6.

Furthermore, isolation insulating layer 6 is formed to extend in the column direction (the vertical direction) at each of terminal end portions (right and left end portions in the figure) of the memory cell array. Accordingly, the memory cell array region is isolated and insulated from other element formation regions by isolation insulating layer 6.

It is noted that the other configuration is almost the same as the configuration of the fifth embodiment. Therefore the same elements will be denoted with the same reference characters and a description thereof will not be repeated.

According to the present embodiment, isolation insulating layer 6 for isolating and insulating memory cells 10 from each other can be omitted, so that the area efficiency in the two-dimensional layout can be improved compared with the fifth embodiment.

### Seventh Embodiment

Although in the foregoing first to sixth embodiments, control gate impurity diffusion region 14 is formed of a single impurity diffusion region (p-type or n-type), it may be formed of a plurality of impurity diffusion regions. Such a configuration will be described below as a seventh embodiment.

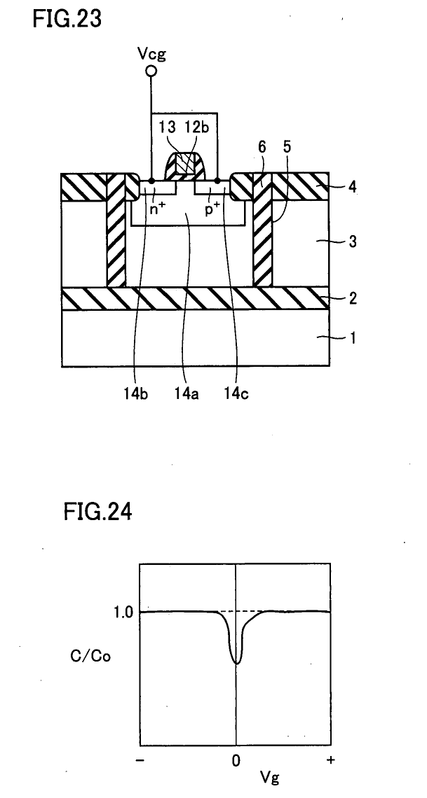

Referring to FIG. 23, the control gate impurity diffusion region has an n-type or p-type region 14a and an n⁺ region 14b and a p⁺ region 14c formed at the surface of region 14a. These n⁺ region 14b and p⁺ region 14c are impurity diffusion regions of mutually opposite conductivity types and are arranged such that a region under floating gate electrode layer 13 is sandwiched therebetween. These n⁺ region 14b and p⁺ region 14c are short-circuited with each other and can receive control gate voltage Vcg.

It is noted that the other configuration is almost the same as any of the first to sixth embodiments. Therefore the same elements will be denoted with the same reference characters and a description thereof will not be repeated.

Referring to FIG. 24, the abscissa Vg indicates a relative voltage value of floating gate electrode layer 13 to control gate voltage Vcg (Vg=Vf−Vcg). The ordinate C/Co indicates a measurement capacity C between semiconductor layer 3 and floating gate electrode layer 13 with respect to an ideal capacity Co between semiconductor layer 3 and floating gate electrode layer 13.

When a positive voltage is applied as control gate voltage Vcg, relative voltage value Vg of floating gate electrode layer 13 becomes negative. Therefore, if a positive voltage as control gate voltage Vcg is high, positive holes gather in that surface of region 14 which opposes floating gate electrode layer 13, so that measurement capacity C between semiconductor layer 3 and floating gate electrode layer 13 becomes approximately equal to ideal capacity Co. Thus, C/Co is 1.

However, if a positive voltage as control gate voltage Vcg is low, positive holes gather poorly in that surface of region 14 which opposes floating gate electrode layer 13. Therefore, measurement capacity C between semiconductor layer 3 and floating gate electrode layer 13 is lower than ideal capacity Co.

On the other hand, when a negative voltage is applied as control gate voltage Vcg, the relative voltage value Vg of floating gate electrode layer 13 becomes positive. Therefore, if a negative voltage as control gate voltage Vcg is high, electrons gather in that surface of region 14 which opposes floating gate electrode layer 13, so that measurement capacity C between semiconductor layer 3 and floating gate electrode layer 13 becomes approximately equal to ideal capacity Co. Thus, C/Co is 1.

However, if a negative voltage as control gate voltage Vcg is low, electrons gather poorly in that surface of region 14 which opposes floating gate electrode layer 13. Therefore, measurement capacity C between semiconductor layer 3 and floating gate electrode layer 13 is lower than ideal capacity Co.

As described above, although the capacity value is low in the vicinity of Vg=0V, impurity diffusion regions 14a, 14b, 14c serve as accumulation layers with other voltage values and thus fulfill the characteristics satisfactorily as a control gate electrode.

### Eighth Embodiment

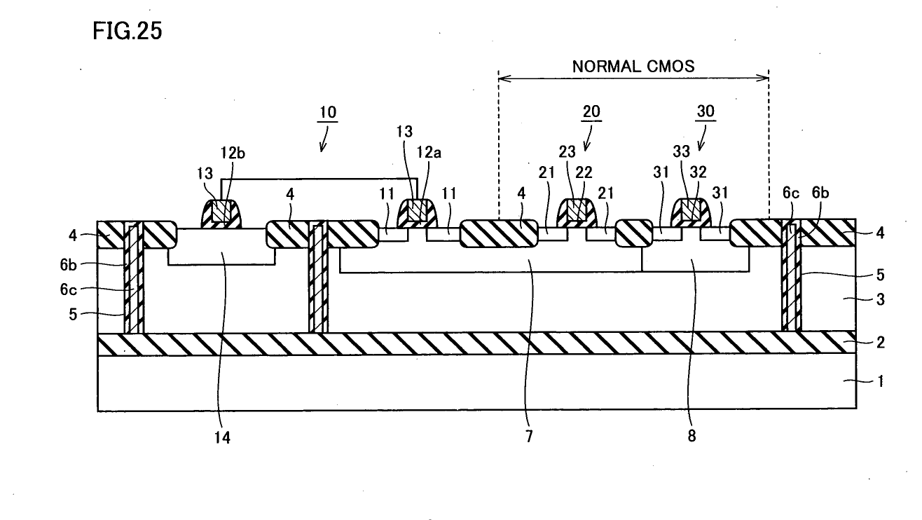

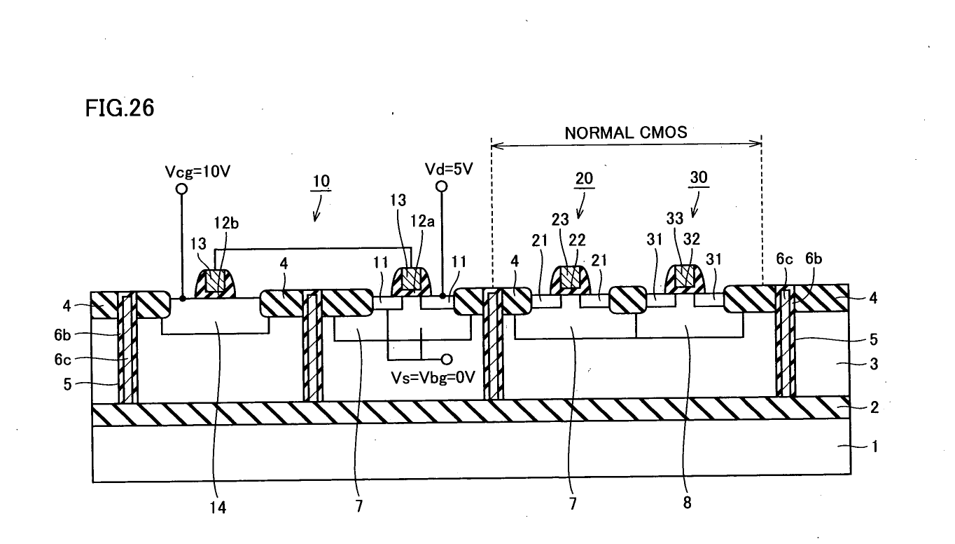

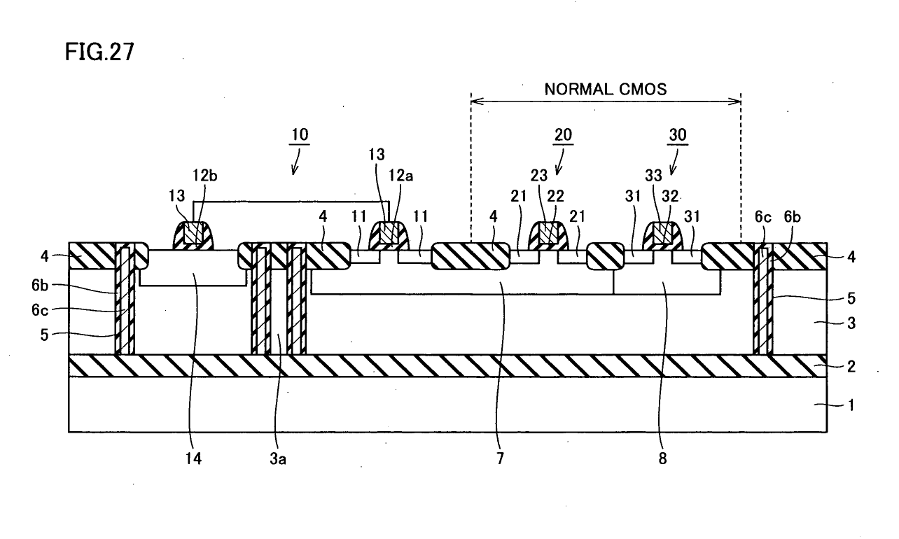

In the foregoing first to seventh embodiments, the configuration in which only isolation insulating layer 6 fills in groove 5 in semiconductor layer 3 has been described. However, as shown in FIG. 25-FIG. 27, an isolation insulating layer 6b formed for example of a silicon oxide film covers the sidewall of groove 5 and another filling layer 6c may fill in groove 5. Filling layer 6c may be, for example, a conductive layer of polysilicon or the like or may be an insulating layer made of any other material.

It is noted that the other configuration is almost the same as any of the first to sixth embodiments. Therefore the same elements will be denoted with the same reference characters and a description thereof will not be repeated.

Now, a method of manufacturing the nonvolatile semiconductor memory device in this embodiment will be described, with attention, in particular, to formation of a groove in a semiconductor layer and filling the groove with an isolation insulating layer.

In the manufacturing method in the present embodiment, first, similar steps as in FIG. 3-FIG. 9 are performed.

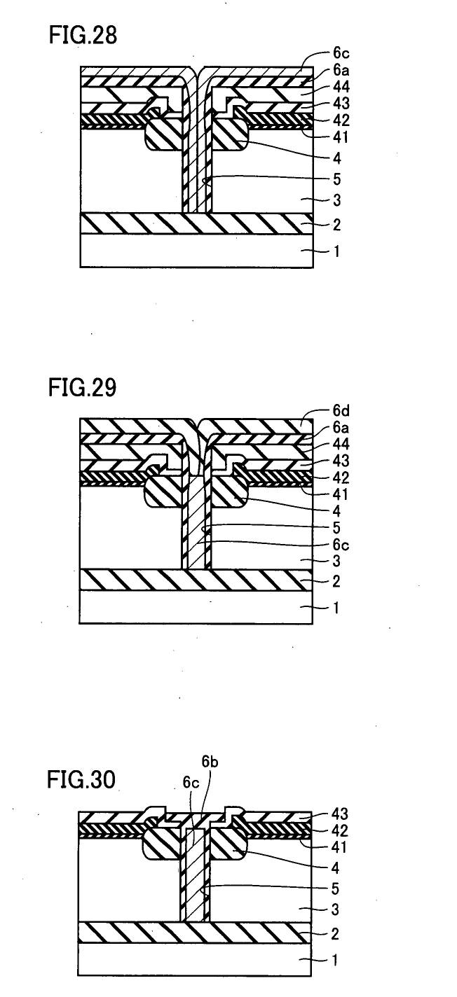

Then, referring to FIG. 28, for example, polysilicon layer 6c is deposited so that polysilicon layer 6c is buried in groove 5. Thereafter, polysilicon layer 6c is etched back until at least the surface of TEOS oxide film 6a is exposed.

Referring to FIG. 29, the aforementioned etch-back allows the surface of TEOS oxide film 6a to be exposed and, in addition, allows polysilicon layer 6c to be left in groove 5, resulting in a filling layer. A TEOS oxide film 6d is formed to cover the surfaces of the exposed TEOS oxide film 6a and filling layer 6c. Thereafter, TEOS oxide films 6d, 6a, 44 are etched away in order until the surface of silicon nitride film 43 is exposed.

Referring to FIG. 30, although the surface of silicon nitride film 43 is exposed to some extent by the aforementioned etching, the etching is further continued until the surface of silicon nitride film 43 is completely exposed. TEOS oxide films 6d, 6a, 44 shown in FIG. 29 are collectively shown as TEOS oxide film 6b in FIG. 30.

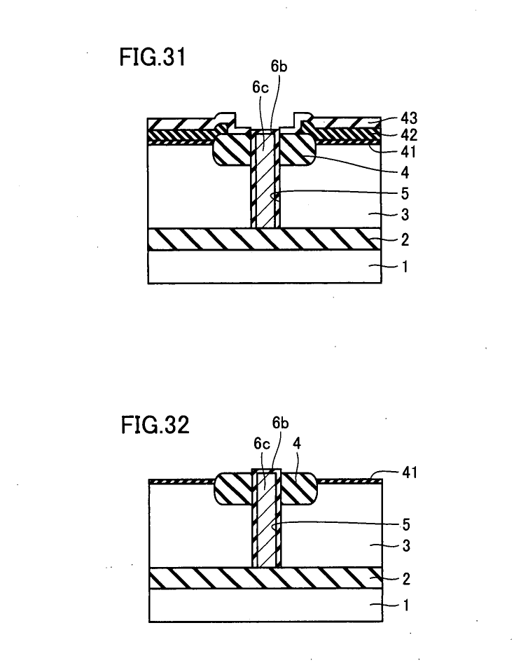

Referring to FIG. 31, the surface of silicon nitride film 43 is completely exposed by the aforementioned etching. The exposed silicon nitride film 43 and the underlying silicon nitride film 42 are successively etched away.

Referring to FIG. 32, the surface of silicon oxide film 41 is exposed by etching the silicon nitride films as described above. Through the aforementioned steps, groove 5 is formed in semiconductor layer 3, and isolation insulating layer 6b covering the sidewall of groove 5 and filling layer 6c filling in groove 5 are formed.

Thereafter, floating gate electrode layer 13, gate electrode layers 23, 33, source/drain regions 11, 21, 31, and the like are formed, thereby completing the nonvolatile semiconductor memory device as shown in FIG. 25-FIG. 27.

Here, the configurations of the foregoing first to eighth embodiments may be applied to an SOI substrate trench isolation process to be used, for example, in Mixed Signal IC for automobiles provided with a power element, so that the 1poly-type nonvolatile memory can be built in, taking advantage of the characteristics of the IC.

The configurations of the foregoing first to eighth embodiments may be formed in an SOI substrate, together with a BiC-DMOS structure having a low-breakdown voltage CMOS transistor, an intermediate-breakdown voltage CMOS transistor, a high-breakdown voltage CMOS transistor, a DMOS (Double diffused MOS) transistor (or a high-breakdown voltage nMOS transistor), a resistance, an npn bipolar transistor and an L-pnp bipolar transistor.

The present invention is advantageously applicable in particular to a nonvolatile semiconductor memory device having a 1poly-type memory cell.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A nonvolatile semiconductor memory device comprising:
a support substrate;
a buried insulating layer formed on said support substrate;
a semiconductor layer formed on said buried insulating layer;
a pair of impurity diffusion regions serving as source/drain formed at a surface of said semiconductor layer;
a floating gate electrode layer formed on said semiconductor layer sandwiched between said pair of impurity diffusion regions with a gate insulating layer interposed;
a control gate impurity diffusion region formed at a surface of said semiconductor layer to oppose said floating gate electrode layer with an inter-gate insulating layer interposed; and
a first isolation insulating layer extending from a surface of said semiconductor layer to reach said buried insulating layer while surrounding a periphery of said control gate impurity diffusion region thereby to separate a region in which said pair of impurity diffusion regions is formed and said control gate impurity diffusion region from each other.

2. The nonvolatile semiconductor memory device according to claim 1, further comprising a second isolation insulating layer extending from a surface of said semiconductor layer to reach said buried insulating layer while surrounding a periphery of said pair of impurity diffusion regions thereby to separate a region in which said pair of impurity diffusion regions is formed from any other element formation region.

3. The nonvolatile semiconductor memory device according to claim 2, wherein said first isolation insulating layer and said second isolation insulating layer partially share an insulating layer portion.

4. The nonvolatile semiconductor memory device according to claim 2, wherein an isolation region formed of a part of said semiconductor layer is provided between said first isolation insulating layer and said second isolation insulting layer.

5. The nonvolatile semiconductor memory device according to claim 1, wherein
said semiconductor layer has a groove extending from a surface of said semiconductor layer to reach said buried insulating layer, and
said groove is filled with said first isolation insulating layer.

6. The nonvolatile semiconductor memory device according to claim 1, wherein
said semiconductor layer has a groove extending from a surface of said semiconductor layer to reach said buried insulating layer, and
said groove is filled with said first isolation insulating layer covering a sidewall of said groove and a filling layer filling in said groove.

7. The nonvolatile semiconductor memory device according to claim 1, wherein
said control gate impurity diffusion region has a pair of control impurity diffusion regions of mutually opposite conductivity types formed at a surface of said semiconductor layer such that a surface of said semiconductor layer under said floating gate electrode layer is sandwiched therebetween.
